(19) United States
(12) Patent Application Publication
(10) Pub. No.: US 2026/0198361 A1
(43) Pub. Date: Jul. 9, 2026

(54) COPPER BUMPS ON COPPER PADS IN SEMICONDUCTOR INTERCONNECT STRUCTURES AND METHODS FOR FORMING THE SAME

(71) Applicant: Taiwan Semiconductor Manufacturing Company Limited, Hsinchu (TW)

(72) Inventors: Wei-Ren Huang, Hsinchu City (TW); Chiang-Jui Chu, Hsinchu (TW); Kuan-Sheng Huang, Kaohsiung City (TW); Ching-Ho Cheng, Hsinchu City (TW); Ching-Wen Hsiao, Hsinchu City (TW)

(21) Appl. No.: 19/008,934

(22) Filed: Jan. 3, 2025

(51) Int. Cl. H01L 23/00

(52) U.S. Cl. CPC H10W 72/20; H10W 72/012; H10W 72/019; H10W 72/90; H10W 70/05; H10W 70/65; H10W 70/66; H10W 72/01235; H10W 72/01951; H10W 72/01953; H10W 72/221; H10W 72/222; H10W 72/223; H10W 72/234; H10W 72/235; H10W 72/252; H10W 72/255; H10W 72/932; H10W 72/952

(57) ABSTRACT

Interconnect bump structures with copper bumps on copper pads. An embodiment interconnect bump structure comprises a first passivation layer; a copper pad on the first passivation layer; a copper bump on the copper pad; a tin-silver bump over the copper bump; and a second passivation layer over the first passivation layer, wherein the copper bump passes through an opening in the second passivation layer.

### BACKGROUND

In the manufacture of semiconductor devices, the quality of the bonding of semiconductor chips to substrates may impact the overall performance and reliability of the final product. The bonding process typically involves the use of metallic interconnections, such as copper bumps, which may serve as the primary means of establishing electrical and mechanical connections between the chip and the substrate. The quality of these connections may be influenced by several factors, including the surface condition of the copper bumps, the wetting behavior of solder materials, and the environmental conditions during bonding.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example interconnect bump structure according to an embodiment disclosed herein.

FIGS. 2A-2K are various cross-sectional views of intermediate structures formed during the formation of the various embodiment interconnect bump structures disclosed herein.

FIG. 3 is a vertical cross-sectional view of an alternative configuration of the interconnect bump structure.

FIG. 4 is a vertical cross-sectional view of an alternative configuration of the interconnect bump structure.

FIG. 5 is a vertical cross-sectional view of an alternative configuration of the interconnect bump structure.

FIG. 6 is a vertical cross-sectional view of an alternative configuration of the interconnect bump structure.

FIG. 7 is a vertical cross-sectional view of an alternative configuration of the interconnect bump structure.

FIG. 8A and FIG. 8B are vertical cross-sectional views illustrating example layer structures of the first passivation layer and the second passivation layer according to various embodiments disclosed herein.

FIG. 9 is a block diagram of an example system for fabricating the interconnect bump structure.

FIG. 10A-10C are vertical cross-sectional views illustrating an example bonding process using the copper bump on the copper pad according to various embodiments disclosed herein.

FIGS. 11A and 11B are vertical cross-sectional views of the interconnect bump structure showing a portion of the second passivation layer at an intersection with the opening in the second passivation layer according to various embodiments disclosed herein.

FIG. 12 is a flow diagram of an example method for fabricating an interconnect bump structure according to various embodiments disclosed herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range. Various embodiments will be described in detail with reference to the accompanying drawings. Wherever possible, the same reference numbers will be used throughout the drawings to refer to the same or like parts. References made to particular examples and implementations are for illustrative purposes and are not intended to limit the scope of the claims.

In some related methods for semiconductor device fabrication, copper bumps are formed on aluminum pads. Aluminum pads may be used, for example, because aluminum may be more cost-effective than copper, both in terms of raw material costs and process handling. Aluminum may also offer greater resistance to corrosion compared to copper. Aluminum pads, however, may result in a high device resistance (Rc). The relatively high device resistances that may occur in devices using aluminum pads may cause signal delays and distortions. This in turn may reduce the maximum frequency at which a circuit may operate and diminish the overall device performance and reliability. Various embodiments disclosed herein seek to enhance the overall performance and reliability of device by using improved bonding pads that may be formed of copper. The copper material may provide lower device resistance. However, such copper bonding pads may be more susceptible to corrosion. Various embodiments disclosed herein utilize an enhanced passivation layer to mitigate such corrosion and further enhance the bonding of materials such as underfill material to enhance the mechanical structure and integrity of devices.

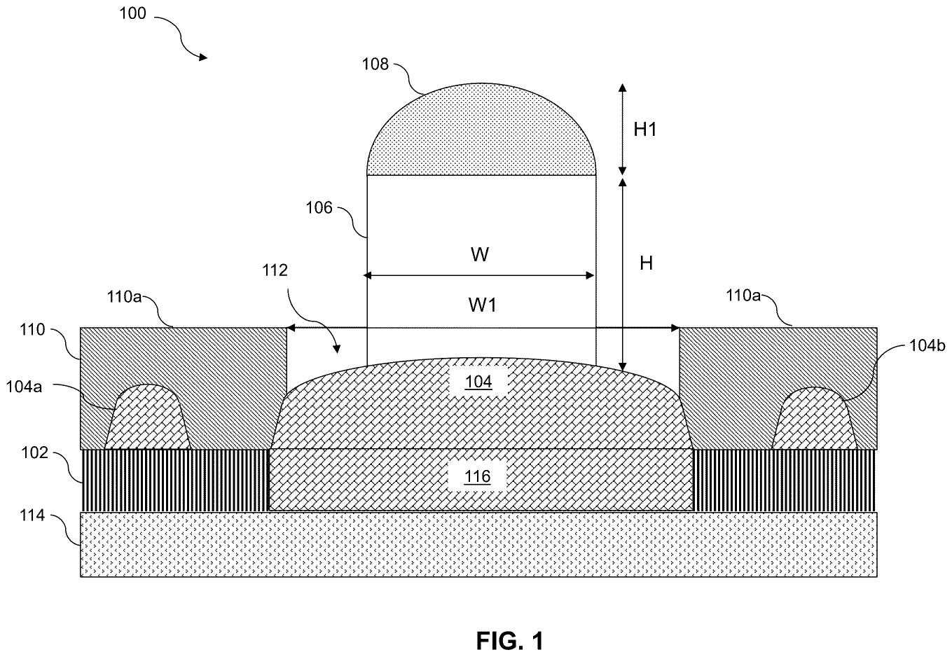

FIG. 1 is a vertical cross-sectional view of an embodiment interconnect bump structure 100. The interconnect bump structure 100 may include a first passivation layer 102 and a copper pad 104 formed within the first passivation layer 102. The first passivation layer 102 may be formed over a substrate 114. For clarity and simplicity, FIG. 1 illustrates the first passivation layer 102 directly over the substrate 114. Various devices and structures formed between the substrate 114 and first passivation layer 102 may be omitted from the figures. However, one of ordinary skill in the art would understand that additional transistor and passive electrical devices (not shown) may be formed over the substrate 114. In addition, electrical interconnect structures may be formed over the substrate 114 between the substrate 114 and the first passivation layer 102. For example, a landing pad 116 of a redistribution layer (RDL) may be electrically contacted to a metal via or metal trace of the RDL formed over the substrate 114. The first passivation layer 102 (sometimes referred to as a capping layer) may provide protection to the electrical devices formed over the substrate 114 but under the first passivation layer 102. For example, the first passivation layer 102 may prevent contaminates and corrosive gases and liquids from fouling the devices and materials formed under the first passivation layer 102.

The interconnect bump structure 100 includes a copper bump 106 formed on the copper pad 104 and a tin-silver bump 108 (also referred to as a solder bump) formed over the copper bump 106. In some embodiments, the tin-silver bump 108 may be directly on top of the copper bump 106. The interconnect bump structure 100 includes a second passivation layer 110 formed over the first passivation layer 102. The copper bump 106 may be formed through an opening 112 in the second passivation layer 110.

In various embodiments disclosed utilize a copper pad 104. The copper pad 104 may enhance the performance of the overall device over devices that utilize aluminum pads. The use of a copper pad 104, instead of an aluminum pad, may reduce the overall resistance of a semiconductor device including the interconnect bump structure 100. For example, forming the copper bump 106 on the copper pad 104 instead of an aluminum pad may reduce the device resistance Rc from 1.8 Ohms to as low as 0.1 Ohms.

Aluminum may naturally form a thin, protective oxide layer, which may prevent further corrosion. However, copper may be more susceptible to corrosion compared to aluminum. For example, copper may have a tendency to oxidize when exposed to air, which may degrade electrical conductivity. The interconnect bump structure 100 may mitigate the susceptibility to corrosion of the copper pad 104 by using the first passivation layer 102 in conjunction with the second passivation layer 110 for enhanced protection of the copper pad 104 from corrosive elements and contaminates.

The first passivation layer 102 and the second passivation layer 110 may be configured to protect any underlying circuits and prevent moisture ingress or mechanical damage while providing electrical isolation. The copper bump 106, capped with the tin-silver bump 108, may act as an interconnect, allowing the interconnect bump structure 100 to bond to another component through a process such as thermal compression bonding or solder reflow.

The tin-silver bump 108 may be a lead-free (LF) solder material. In some embodiments, the tin-silver bump 108 is re-flowed during the bonding process to form a reliable electrical and mechanical connection between two components of the interconnect bump structure 100. This type of bump metallurgy is well-suited for applications requiring high thermal stability and robust mechanical performance, such as in devices exposed to repeated thermal cycling or high-power operations.

The interconnect bump structure 100 may be used in advanced packaging technologies, for example, in flip-chip designs. In some embodiments, the interconnect bump structure 100 is configured for use in high-performance integrated circuits (ICs), such as microprocessors, graphics processing units (GPUs), and system-on-chip (SoC) devices, where efficient electrical and thermal connections are useful for meeting design targets. The interconnect bump structure 100 may be used in applications requiring high input/output (I/O) density and excellent thermal performance. For example, the interconnect bump structure 100 may be used in devices that are used in data centers for server processors, where efficient heat dissipation and reliable electrical connections are useful due to the continuous computational processing demands that create large amounts of heat.

In some embodiments, the first passivation layer 102 and the second passivation layer 110 are insulating layers configured to protect the underlying circuitry from environmental contaminants, mechanical damage, and chemical reactions. The first passivation layer 102 and the second passivation layer 110 may also help to reduce surface states, which can degrade the electrical performance of the resulting semiconductor device. Two separate passivation layers may be used, for example, such that the first passivation layer 102 provides protection to underlying circuitry while the second passivation layer 110 provides protection for the copper pad 104.

The first passivation layer 102 may be applied over a substrate 114. The first passivation layer 102 may serve as a protective barrier. In some embodiments, the first passivation layer 102 is made from materials such as silicon dioxide (SiO2) or silicon nitride (Si₃N₄). The first passivation layer 102 may also electrically isolate the copper pad 104 from other parts of the interconnect bump structure 100.

The second passivation layer 110, which may partially or completely surround the copper bump 106, may provide an enhanced level of protection and mechanical stability. The second passivation layer 110 may be patterned to expose specific areas, such as the copper pad 104, where bonding or interconnections will occur. The second passivation layer 110 may also be made from similar dielectric materials as the first passivation layer 102 such as silicon nitride or polyimides, depending on the process requirements. In some embodiments, the second passivation layer 110 may provide a border to ensure the copper bump 106 and copper pad 104 are properly aligned and protected during bonding, for example, thermal compression bonding.

The copper pad 104 may be deposited on the landing pad 116 of the RDL. The copper pad 104 may be electrically connected to underlying circuitry and/or device through, for example, the bonding pad, vias or interconnect traces of the redistribution layer. The copper pad 104 may be configured, by appropriate geometry, to meet design targets for electrical performance, mechanical integrity, and compatibility with bonding techniques. In flip-chip designs, the copper pad 104 may be configured as the anchor point for the copper bump 106, which in turn interfaces with the package substrate or interposer.

For example, the copper pad 104 may be configured as a bare copper surface, where the pad is exposed for direct bonding to the bump. This configuration may include an optional surface finish like nickel-gold (Ni—Au) plating to enhance the bondability and prevent oxidation. The thickness of the copper pad 104 and the choice of surface finish are selected based on the specific requirements of the interconnect bump structure 100, such as thermal performance and mechanical strength.

Another example configuration includes passivated copper pads, where the copper pad 104 may be partially or fully surrounded by dielectric materials, such as silicon dioxide or silicon nitride, which are part of the first passivation layer 102 and/or second passivation layer 110 of the interconnect bump structure 100. In these configurations, the copper pad 104 is left exposed only in defined regions where bonding occurs, while the first passivation layer 102 and second passivation layer 110 may protect the edges of the copper pad 104 from corrosion and contamination. This configuration may be advantageous in applications where long-term reliability is critical, as the configuration mitigates the effects of environmental factors, such as moisture or temperature cycling.

In some embodiments, the interconnect bump structure 100 includes one or more redistribution layers (RDL) used in conjunction with the copper pad 104. In an RDL configuration, the copper pad 104 may be extended to reposition the bond site or to route the electrical signal to a different location on the die. This may provide for more flexibility in bump placement, and more flexibility in bump placement may enable higher interconnect densities and better signal routing in complex designs. RDL configurations may be useful, for example, in applications such as system-in-package (SiP) and heterogeneous integration, where multiple chips are packaged together.

The copper bump 106 may be configured as the primary interconnect between a semiconductor die and another component. The copper bump 106 may be formed, for example, using an electroplating process. In an electroplating process, a copper layer is deposited on top of the copper pad 104 through a patterned photoresist mask. The copper bump 106 provides a low-resistance electrical path and excellent thermal conductivity. The copper bump 106, due to its low electrical resistance, may be particularly useful for high-performance applications that require efficient signal transmission and heat dissipation.

The shape of the copper bump 106 in semiconductor packaging may be cylindrical and/or slightly domed. The shape of the copper bump 106 may be configured for efficient bonding and reliable electrical performance in a specified application. For example, the width of the copper bump 106 may be increased to facilitate a higher bandwidth communications signal, or the width of the copper bump 106 may be decreased to reduce the size of a package for mobile applications. The height of the copper bump 106 may vary, but may be taller than it is wide, especially in configurations like copper pillar bumps, where a narrow diameter supports fine-pitch applications.

The base of the copper bump 106 may be broader, tapering slightly as it extends upward to form a well-defined, smooth profile. This shape may be selected to ensure uniform contact and to distribute mechanical stress evenly during bonding and subsequent thermal cycles. The top of the copper bump 106 may be flat or slightly rounded, depending on whether it is intended for direct thermal compression bonding or solder reflow. For example, a flat top may be more suitable for direct thermal compression, and a slightly rounded top may be more suitable for solder reflow. In alternative designs, such as micro-bumps used in 3D integrated circuits (ICs), the bump may be much smaller and more rounded, optimizing it for higher-density connections. Variations in bump height and shape allow for different mechanical and electrical properties, tailored to specific device needs, such as minimizing inductance or optimizing thermal performance. For example, inductance may be reduced by increasing the diameter of the copper bump 106 and/or reducing the height of the copper bump 106. In another example, heat conductance may be increased by increasing the volume of the copper bump 106, for instance, by increasing the diameter and height of the copper bump 106.

In some embodiments, the copper bump 106 is a copper pillar bump, which features a taller and narrower bump structure compared to other related copper bumps. Copper pillar bumps may be used in high-density packaging, such as in fine-pitch applications, where bump spacing may be minimized to accommodate more input/output (I/O) connections. The taller and narrower bump design may enable finer pitches and is used in applications like advanced memory chips, high-performance processors, and system-on-chip (SoC) devices.

The tin-silver (SnAg) bump 108 is composed of a widely used solder material in semiconductor packaging, particularly in lead-free designs where environmental regulations mandate alternatives to traditional lead-based solders. SnAg is an alloy typically composed of around 96.5% tin and 3.5% silver, though variations in composition are possible depending on specific performance requirements. The alloy is known for its high melting point (around 221° C.) and good mechanical properties. The SnAg alloy may be suitable for applications that require reliable connections under thermal and mechanical stress. The tin-silver bump 108 may be applied (for example, via electrical plating) over the copper bump 106 during a later or final stage of packaging to form a robust interconnect through solder reflow.

The shape of the tin-silver bump 108 may be spherical or slightly dome-shaped. The shape of the tin-silver bump 108 may be configured to maximize the contact area during reflow and ensure uniform wetting of the contact surface. For example, a spherical shape of the tin-silver bump 108 that results from surface tension forces may increase contact with an opposing component because it provides a large, smooth, and symmetric surface that can spread out and wet the opposing component. In some embodiments, as the solder melts during reflow, the bump slightly flattens, creating a reliable bond that distributes mechanical stresses evenly. For example, a slightly flattened bump may have a larger contact area compared to a perfect spherical shape, and the increased surface area may allow for a more uniform distribution of forces across the tin-silver bump 108. In contrast, a more spherical bump may have a smaller contact area, potentially concentrating mechanical forces, for example, along the edges or at an interface with a bonding surface.

This spherical or dome-shaped geometry may be useful, for example, in absorbing thermal expansion mismatches between the semiconductor die and the substrate, reducing the risk of cracking or delamination during thermal cycling. Additionally, the rounded shape may reduce or minimize voids within the solder joint, ensuring consistent electrical and mechanical performance over the device's lifetime. The size of the tin-silver bump 108 may vary depending on the pitch and application, with smaller bumps typically used in fine-pitch designs where higher I/O densities are required.

In some embodiments, tin-silver-copper (SAC) alloys, such as SAC305 (96.5% Sn, 3.0% Ag, 0.5% Cu), may be used to improve solder joint reliability. The addition of copper enhances the alloy's resistance to electromigration and thermal fatigue, making SAC alloys suitable for high-reliability applications, such as automotive or aerospace electronics. Tin-bismuth (SnBi) alloys are another alternative, offering a lower melting point, which can be advantageous in applications where thermal budgets are limited.

For devices in which very fine bump pitches or lower standoff heights is desired, micro-bumps made from SnAg may be used. These bumps may be much smaller (e.g., to meet design requirements to fit into mobile devices), often in the range of tens of microns, and their shape may more strongly impact the resulting bond integrity at such small scales. In these configurations, the tin-silver bump 108 may have a more uniform and flatter profile to minimize height and ensure precise alignment during bonding.

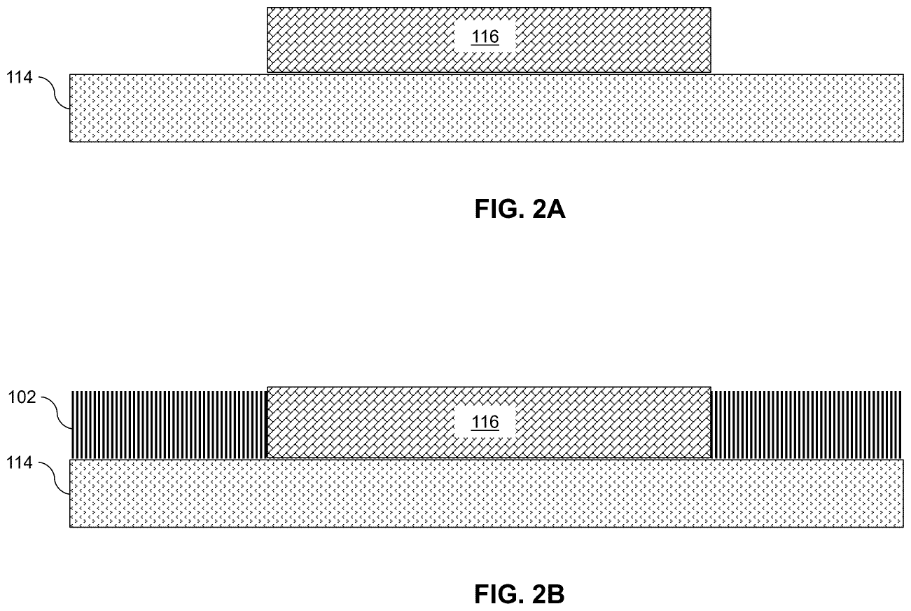

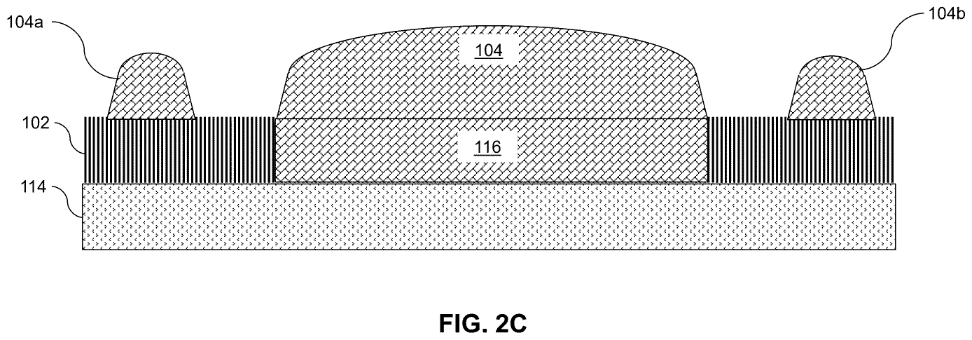

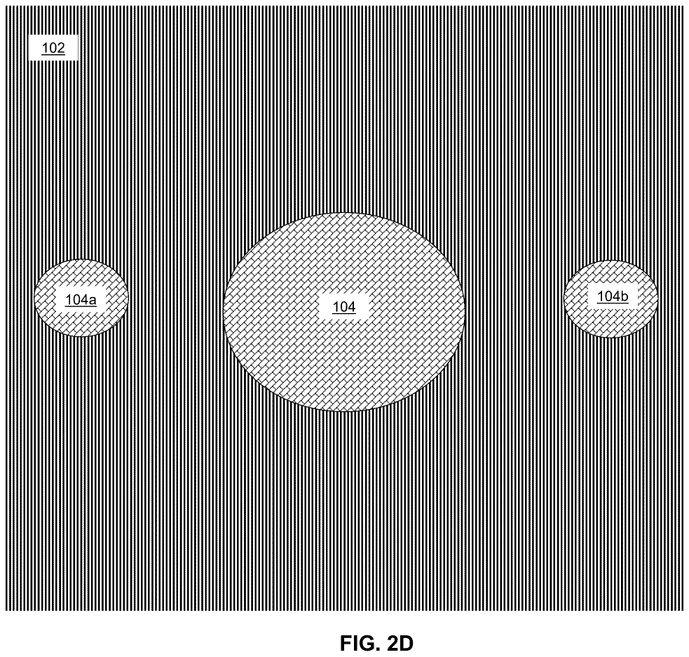

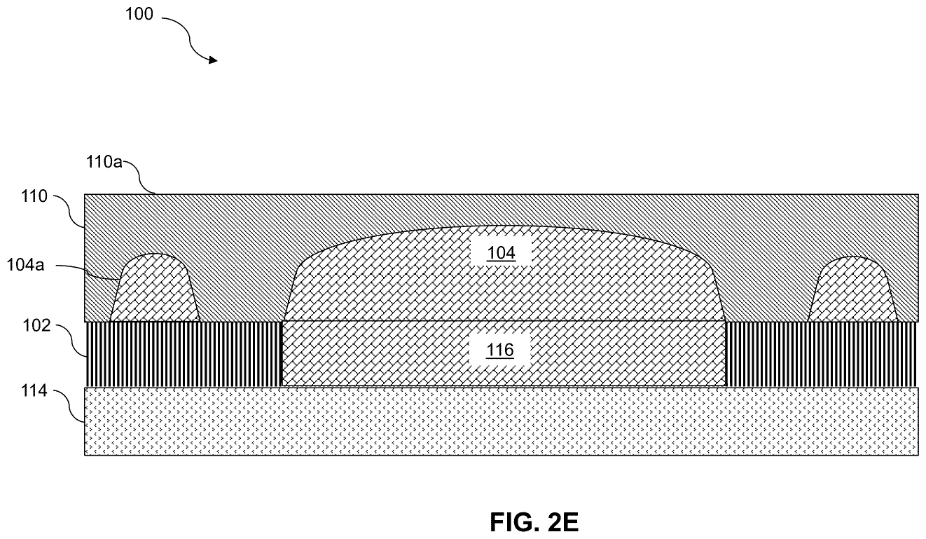

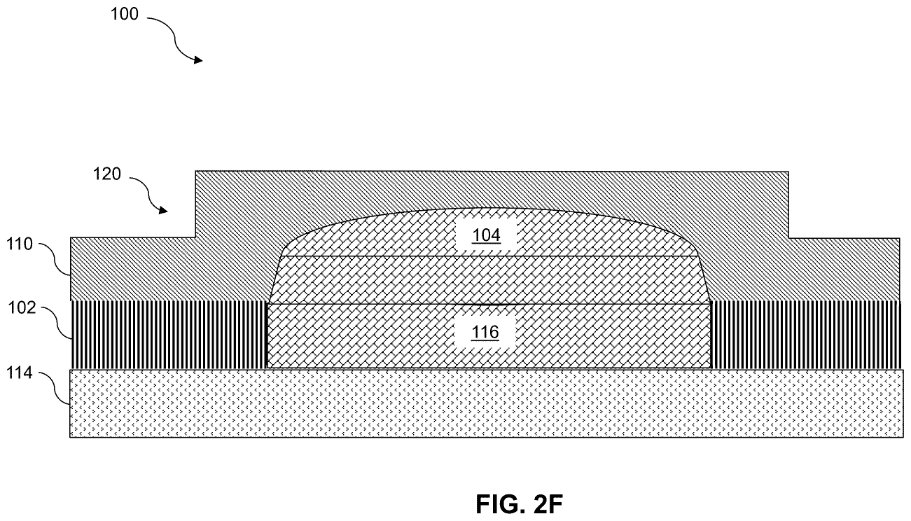

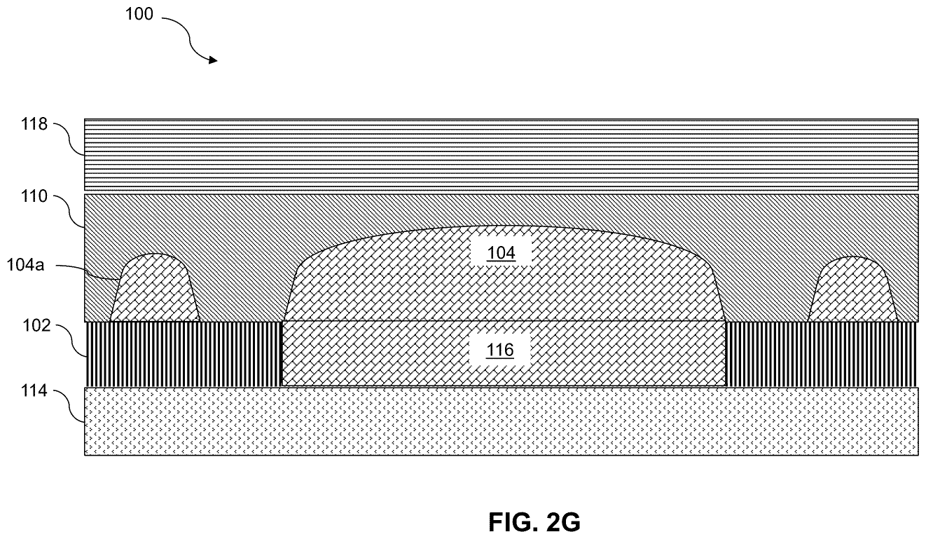

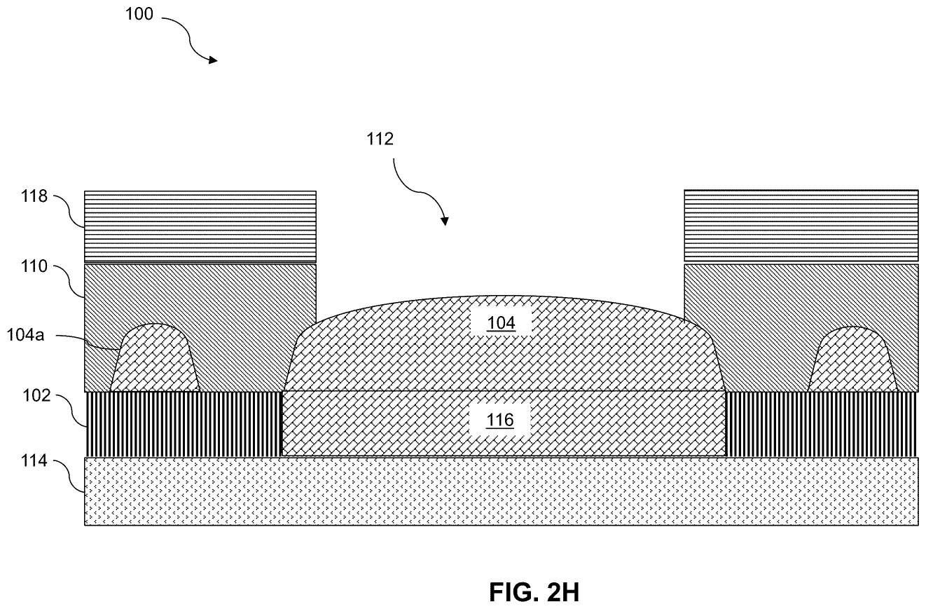

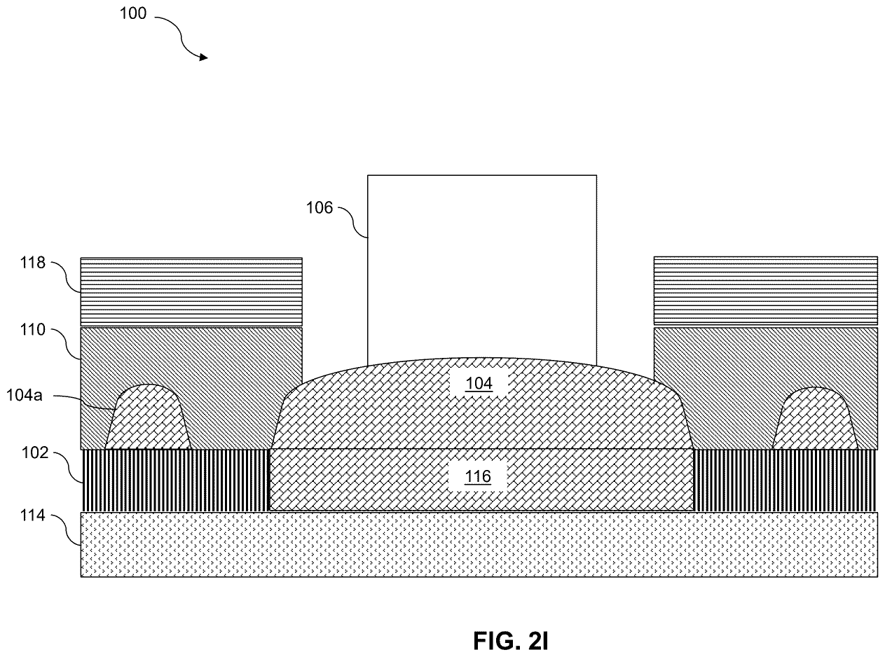

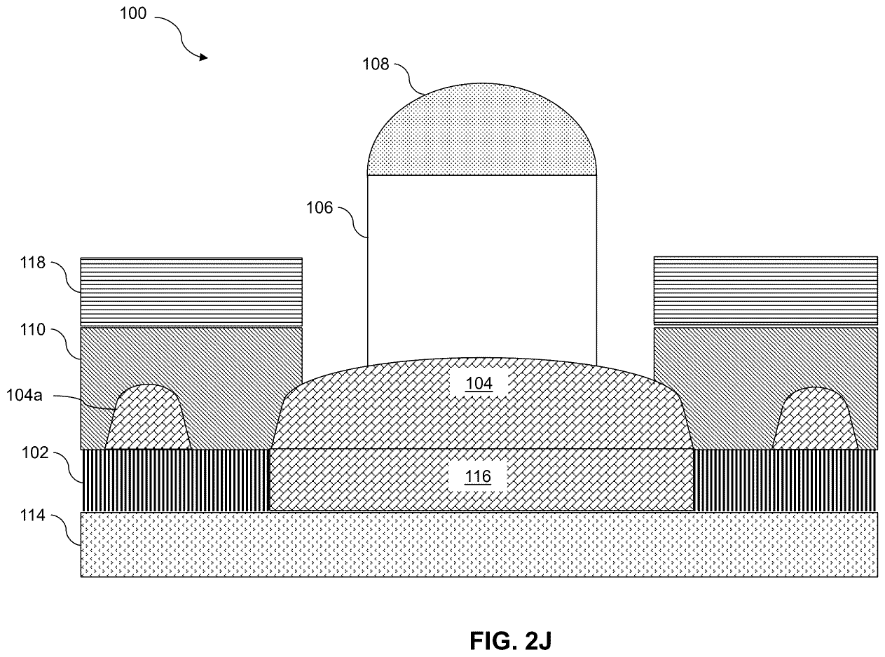

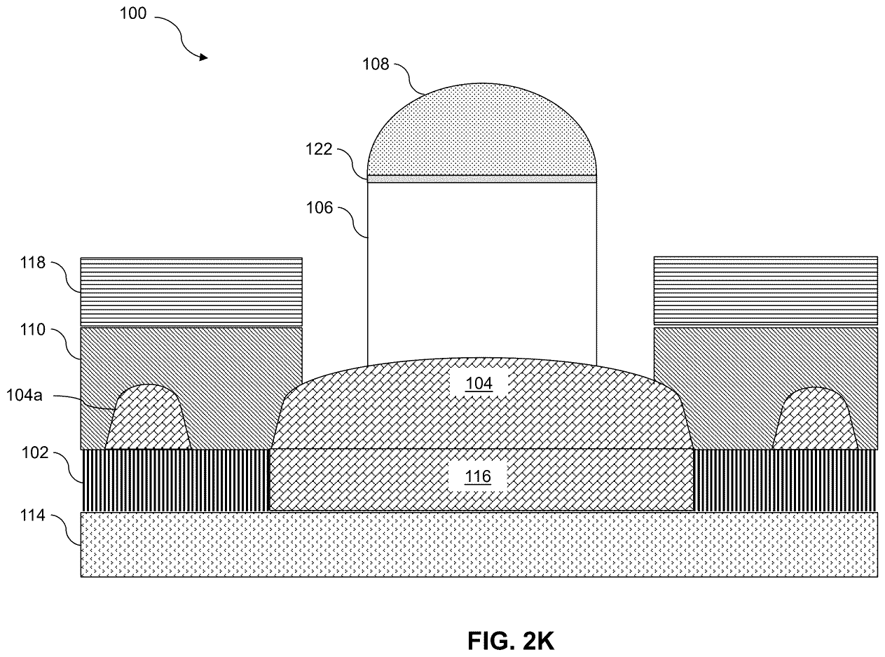

The interconnect bump structure 100 may include a dummy structure 104a, 104b that is adjacent to the copper pad 104. The dummy structure 104a, 104b may be formed of copper and deposited along with the copper pad 104. The dummy structure 104a, 104b may include a first pad 104a on a first side of the copper pad 104 and a second pad 104b on a second side of the copper pad 104 opposite the first side. The dummy structure 104a, 104b may be electrically isolated from the rest of the interconnect bump structure 100. The dummy structure 104a, 104b instead provides structural support for the second passivation layer 110. The presence of the dummy structure 104a, 104b may allow the second passivation layer 110 to have a substantially flat top surface 110a as described further below with reference to FIGS. 2A-2F.

As shown in FIG. 1, the copper bump 106 may have a height H in the vertical direction and a width W in the horizontal direction. The height H is typically measured from the center of the copper pad 104; however, the height H may alternatively be measured from the edges of the copper pad 104 or at any other appropriate location. The opening 112 in the second passivation layer 110 has a width W1 in the horizontal direction. The height of the tin-silver bump 108 has a height H1 in the vertical direction.

In some embodiments, the copper bump 106 has a height H between 22 μm and 28 μm, inclusive. In some embodiments, the tin-silver bump 108 has a height H1 between 15 μm and 19 μm, inclusive. In some embodiments, the opening 112 in the second passivation layer 110 has a width W1 between 32 μm and 43 μm, inclusive.

In some embodiments, a ratio R_{W} between the width W of the copper bump 106 to the width W1 of the opening 112 in the second passivation layer 110 is between 0.4 and 2, inclusive. That is to say, in some embodiments the width W of the copper bump 106 may be less than the width W1 of the opening 112. In other embodiments, the width W of the copper bump 106 may be greater than the width W1 of the opening 112. In instances where the copper bump 106 has a smaller footprint than the opening 112 (i.e., R_{W}<1), the second passivation layer 110 may partially shield the copper bump 106, potentially protecting it from oxidation and environmental exposure. In instances where the copper bump 106 extends beyond the opening 112 (i.e., R_{W}>1), the contact area for bonding may be larger, which may be useful for the mechanical and electrical connection to subsequent layers such as the tin-silver bump 108.

In some embodiments, a ratio R_{H} between the height H of the copper bump 106 and the height H1 of the tin-silver bump 108 is between 1 and 3, inclusive. That is to say that the height H of the copper bump 106 may be greater than the height H1 of the tin-silver bump 108. R_{H} values closer to the lower end may be advantageous for flexible and mechanically compliant designs, while higher ratios may prioritize electrical and structural robustness.

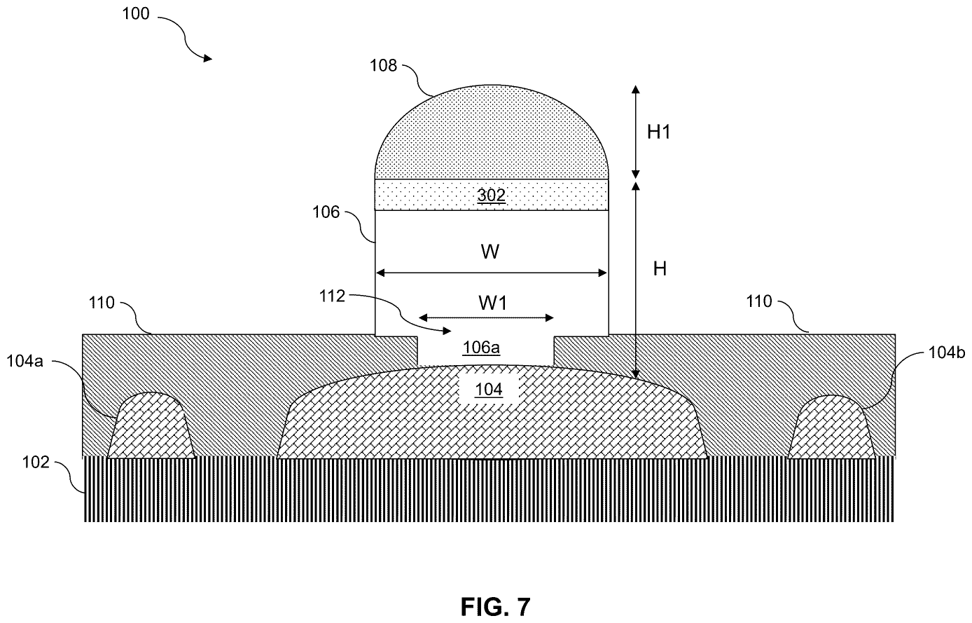

In the example, shown in FIG. 1, the width W1 of the opening 112 in the second passivation layer 110 is greater than the width W of the copper bump 106. FIG. 7 illustrates an embodiment in which the width W1 is less than the width W of the copper bump 106. As a result, the copper bump 106 includes a narrow base portion 106a having a width that is substantially the same as the width W1 of the opening 112 in the second passivation layer 110.

FIGS. 2A-2K illustrate example intermediate structures that may be formed during the process for forming the interconnect bump structure 100. FIG. 2A is a vertical cross-section view that shows the formation of a landing pad 116 of a redistribution layer (RDL) on a substrate 114. The RDL is generally fabricated over the substrate 114 and comprises conductive traces and vias that redistribute the electrical connections, for example, from internal circuitry to external pads. This redistribution allows for a different arrangement or spacing of the contact points, typically to match the bump layout used for bonding.

The RDL may include a metallization pattern in insulating layers. The metallization pattern may include copper and the insulating layer may include a polymer. The metallization pattern may include a landing pad 116 electrically connected to an external connector (i.e., copper bump 106), and the copper bump 106 may include a tapered portion connecting the landing pad 116 to a conductive line in a top-down view, where a width of the tapered portion decreases from the landing pad 116 to the conductive line. The substrate 114 may be a silicon wafer.

FIG. 2B is a vertical cross-sectional view that shows the formation of the first passivation layer 102. After the landing pad 116 is patterned on the substrate 114, the first passivation layer 102 may be deposited. Selective etching may be performed to create openings where a pad will make contact with the landing pad 116. In other embodiments, a planarization process such as a chemical mechanical polishing (CMP) process may be performed to create co-planer top surfaces of the landing pad 116 and first passivation layer 102. This allows the subsequent pad metallization to connect with the landing pad 116 at designated points.

FIG. 2C is a vertical cross-section view that shows the formation of the copper pad 104 over the landing pad 116 and above the first passivation layer 102. FIG. 2C also shows the formation of the dummy structure 104a, 104b that may be adjacent to the copper pad 104. The copper pad 104 and the dummy structure 104a, 104b may be formed by electrodeposition.

FIG. 2D is a top-down view of the copper pad 104 and the dummy structure 104a, 104b. The copper pad 104 may have a circular shape and the dummy structure 104a, 104b may include two circular pads 104a, 104b on opposite sides of the copper pad 104. In some embodiments, the copper pad 104 has a square shape and each of the pads 104a, 104b may also have a square shape. Other shapes are within the contemplated scope of disclosure.

FIG. 2E is a cross-sectional vertical view that shows the formation of the second passivation layer 110. The second passivation layer 110 may have a substantially flat top surface 110a by virtue of the dummy structure 104a, 104b supporting the second passivation layer 110 from underneath the second passivation layer 110. The substantially flat top surface 110a may be useful, for example, to reduce void formation during an underfill process. Void formation may induce layer delamination and reduce reliability of the resulting device.

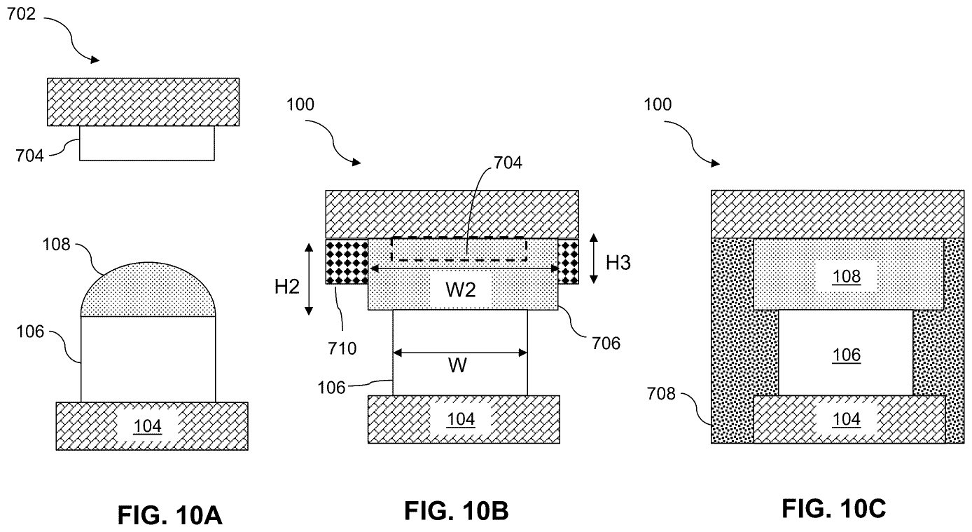

FIG. 2F is a cross-sectional vertical view that illustrates the interconnect bump structure 100 without the dummy structure 104a, 104b to illustrate the effectiveness of the use of the dummy structure 104a, 104b. The second passivation layer 110 falls away from the copper pad 104, creating corners 120 where undesirable voids may form during a subsequent underfill process, for example, an underfill process as described further below with reference to FIG. 10C.

FIG. 2G is a cross-sectional vertical view that illustrates the formation of an optional polyimide layer 118 over the second passivation layer 110. The polyimide layer 118 may be formed over the second passivation layer 110, for example, by spin-coating or spray-coating a liquid polyimide precursor, followed by a soft bake to remove solvents. The polyimide may be cured through a thermal process.

FIG. 2H is a cross-sectional vertical view that illustrates the formation of an opening 112 in the polyimide layer 118 (if present) and the second passivation layer 110. Forming the opening 112 may include, for example, a photolithography and etching process. A photoresist may be applied and patterned to define the area of the opening 112. Reactive ion etching (RIE) or wet etching may be used to selectively remove the polyimide and underlying passivation materials, exposing the copper pad 104.

FIG. 2I is a cross-sectional vertical view that illustrates the formation of the copper bump 106 on the copper pad 104. The copper bump 106 may be formed, for example, using an electroplating process. In an electroplating process, a copper layer is deposited on top of the copper pad 104 through a patterned photoresist mask.

FIG. 2J is a cross-sectional vertical view that illustrates the formation of a tin-silver bump 108 on the copper bump 106. The tin-silver bump 108 may be applied by solder deposition and, in some embodiments, reflowed to form a dome shape.

FIG. 2K is a cross-sectional vertical view that illustrates that intermetallic compounds (IMCs) 122 may be formed at an interface between the tin-silver bump 108 and the copper bump 106, for example, due to the chemical interaction between tin and copper at elevated temperatures, such as those experienced during reflow soldering or thermal bonding processes. The thickness and morphology of these IMCs 122 may depend on factors such as temperature, duration of thermal exposure, the composition of the tin-solder bump 108, and the surface condition of the copper bump 106. The copper bump 106 and the tin-silver bump 108 may collectively form a conductive terminal providing an electrical connection for a ground or power supply voltage between the bump structure and an external component.

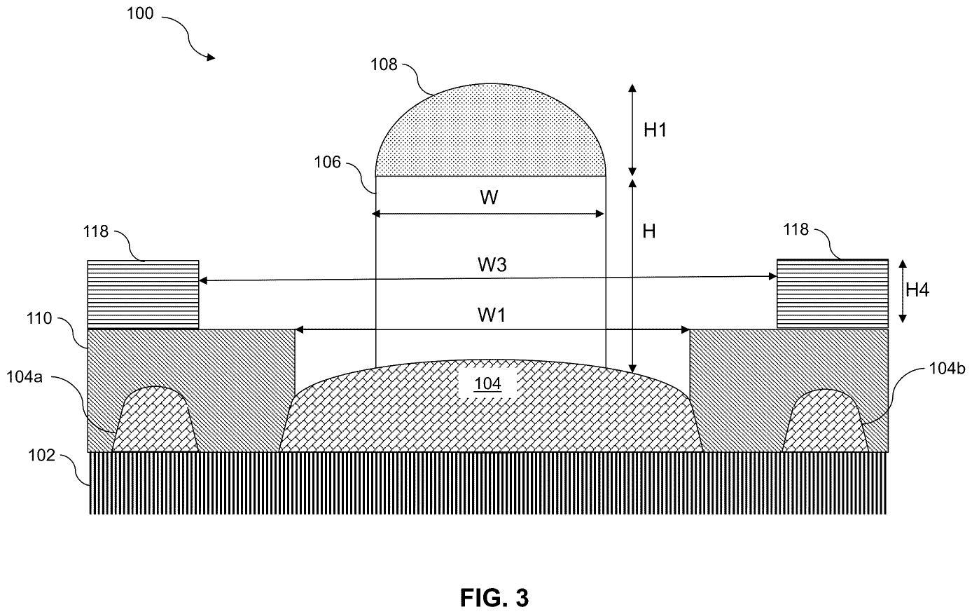

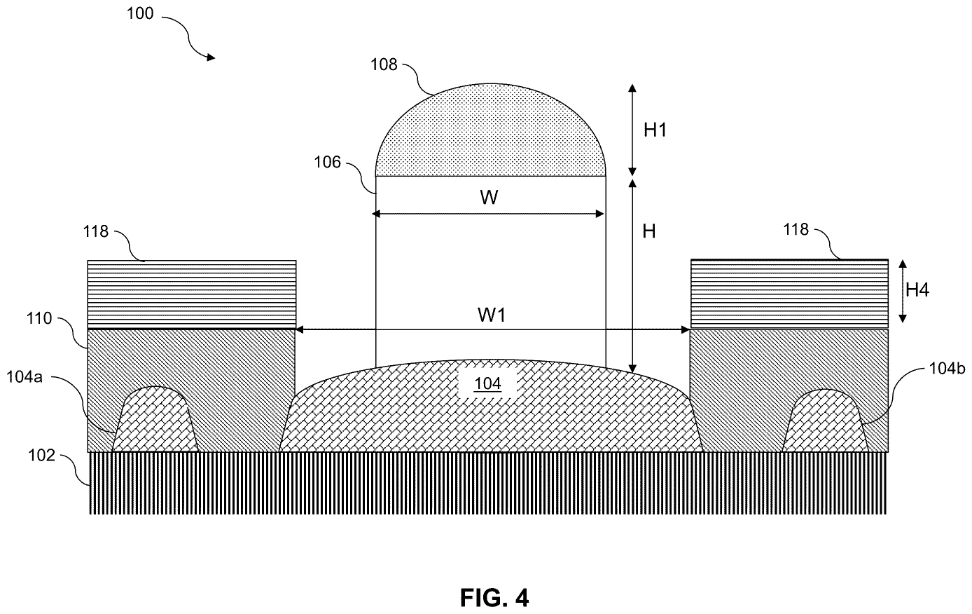

FIG. 3 shows an alternative embodiment of the interconnect bump structure 100 including a polyimide layer 118 to increase underfill material adhesion. The copper bump 106 may be formed through an opening in the polyimide layer 118 having a width W3, and the polyimide layer 118 may have a thickness H4 in the vertical direction. The thickness H4 may be between 2 μm and 5 μm, inclusive. The width W3 may be between 32 μm and 50 μm, inclusive. FIG. 4 shows an alternative embodiment of the interconnect bump structure 100 where the sidewall of the polyimide layer 118 is coincident with the sidewall of the second passivation layer 110. In this embodiment, the width W3 of the opening in the polyimide layer 118 may be equal to the width W1 of the opening 112 in the second passivation layer 110.

The polyimide layer 118 may be useful, for example to provide mechanical support and protect solder joints from thermal and mechanical stresses. Polyimide may be used for this layer due to its excellent mechanical strength, chemical resistance, and thermal stability, which make it suitable for the harsh conditions of semiconductor processing. Additionally, polyimide has a relatively low dielectric constant, making it useful in maintaining signal integrity in high-frequency applications. The flexibility of polyimide may allow it to absorb stress and prevent damage to the underlying structures.

The formation of the polyimide layer 118 may begin with the spin-coating of a liquid polyimide precursor (often a polyamic acid) onto the interconnect bump structure 100, which already has the second passivation layer 110 in place. After spin-coating, the interconnect bump structure 100 may undergo a soft bake process to remove solvents and partially cure the polyimide. Following the soft bake, the polyimide may be subjected to a patterning process, for example, which involves photolithography and etching to define openings for contact pads or other interconnect structures.

After patterning, the polyimide may be fully cured in a high-temperature oven, which thermally converts the polyamic acid to polyimide. The resulting polyimide layer 118 is a highly stable and mechanically robust layer. This cured polyimide layer 118 provides a surface with excellent adhesion properties for the underfill material; moreover, the polyimide layer 118 may ensure proper mechanical support for the package during thermal cycling and mechanical stress.

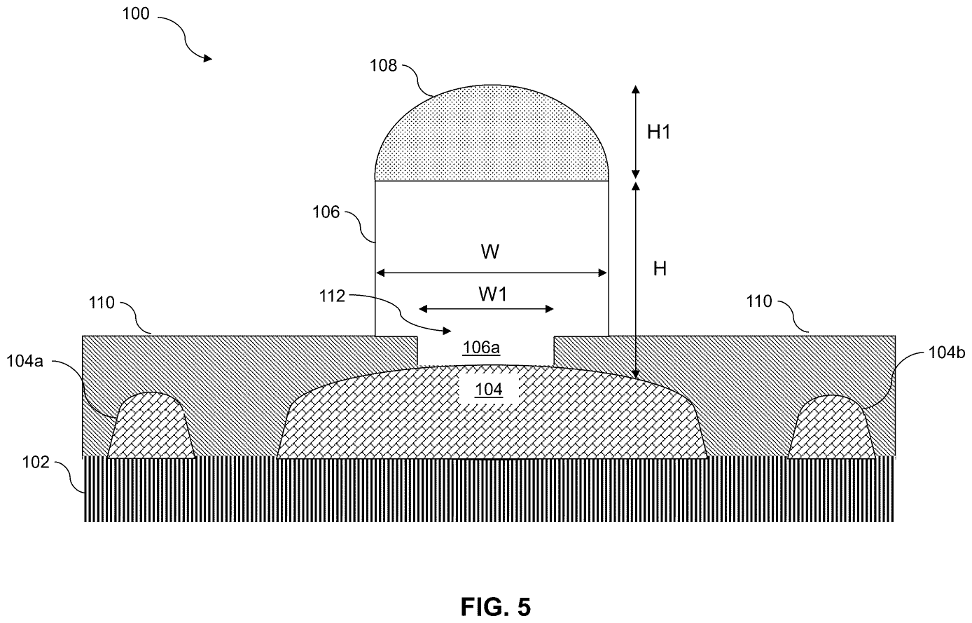

In some embodiments, the copper pad 104, being easily oxidized, benefits from the design in which the second passivation layer 110 includes an opening 112 smaller than the width W of the copper bump 106. In this configuration, the narrow base portion 106a of the copper bump 106 passes through the opening 112, allowing the second passivation layer 110 to cover a larger portion of the copper pad 104. This configuration, as shown in FIG. 5, offers enhanced protection as compared to the embodiments illustrated in FIGS. 1-4, where the opening 112 in the second passivation layer 110 is wider, exposing more of the copper pad 104 surface. The reduced exposure of the copper pad 104 to environmental elements, such as moisture and oxygen, in FIG. 5 mitigates against oxidation. Such oxidation may degrade the electrical performance and mechanical reliability of the copper pad 104 over time. By limiting the exposed surface area, the embodiment as illustrated in FIG. 5 (and in FIG. 7) may also reduce the likelihood of corrosion and other forms of chemical degradation that could negatively impact the long-term durability of the interconnect.

In contrast, FIGS. 1-4, for example, illustrate a configuration in which the opening 112 in the second passivation layer 110 is wider, allowing the copper bump 106 to have a broader base in direct contact with the copper pad 104. While this may simplify the bonding process (for example, providing a larger target for bonding) and provide a larger surface area for the bump-pad connection, it may also leave more of the copper pad 104 vulnerable to oxidation.

Alternatives to the embodiment configuration illustrated in FIG. 1 may include applying a protective metal finish, such as nickel-gold (Ni-Au) or a thin barrier layer, to the copper pad 104 to mitigate oxidation while maintaining the larger bump-pad contact area. However, the design in FIG. 5 may reduce the need for additional protective layers by using the second passivation layer 110 material itself as a shield; the resulting configuration may reduce manufacturing complexity and cost while improving the oxidation resistance of the copper pad 104.

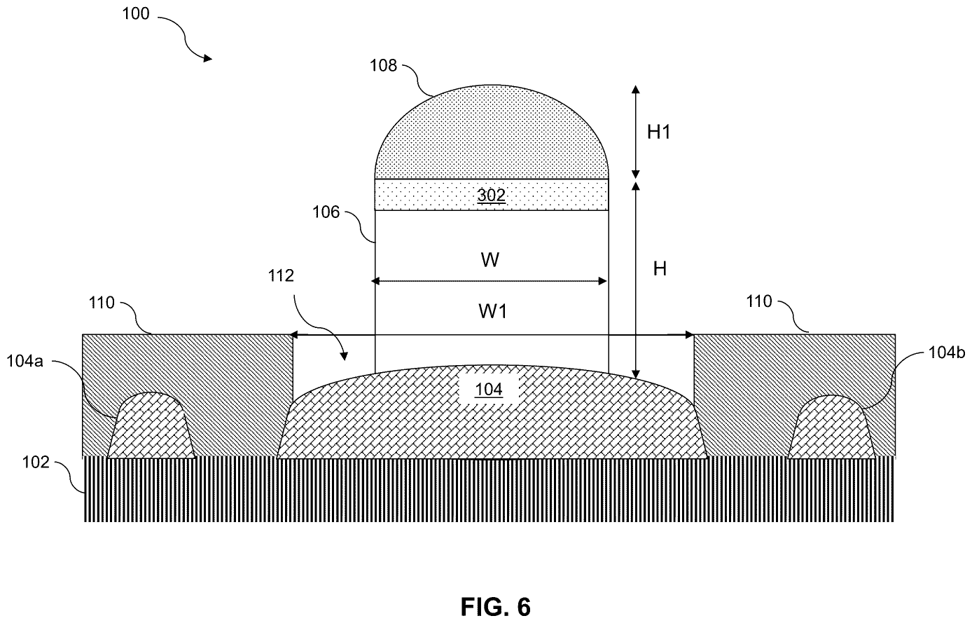

FIG. 6 is a cross-sectional vertical view of an alternative embodiment configuration of an interconnect bump structure 100 having a nickel layer 302 on the copper bump 106. The tin-silver bump 108 may be formed over the nickel layer 302. The inclusion of a nickel layer 302 on the copper bump 106, as shown in FIG. 6, may serve multiple functions in semiconductor packaging. Nickel (Ni) is commonly used as a diffusion barrier layer between the copper bump 106 and the tin-silver bump 108.

One role of the nickel layer 302 may be to prevent copper from diffusing from the copper bump 106 into the solder material of the tin-silver bump 108 during the reflow process and over the lifespan of the device. Copper diffusion into the tin-silver bump 108 (e.g., solder) may result in the formation of brittle intermetallic compounds (IMCs), which may degrade the mechanical strength and reliability of the solder joint. By introducing the nickel layer 302, the formation of excessive IMCs may be mitigated. The mitigation of IMCs may enhance the long-term mechanical and electrical stability of the interconnect. IMCs may be formed between the nickel layer 302 and the copper bump 106; however, the interaction between the nickel layer 302 and the copper bump 106 may be insignificant as compared to the potential interaction between the copper bump 106 and the tin-silver bump 108. The IMCs that form between the nickel layer 302 and the copper bump 106 may not significantly affect the mechanical or electrical properties of the joint.

Another potential advantage of the nickel layer 302 is its role in improving the bondability and wettability of the tin-silver bump 108 (e.g., solder) to the copper bump 106. Nickel may provide a more reliable surface for the solder to adhere to, especially in high-performance applications where the mechanical integrity of the solder joint is highly desired. Furthermore, nickel resists oxidation better than copper, offering an additional layer of protection for the copper bump during manufacturing and operation. This resistance to oxidation contributes to the reliability of the device, for example, in environments where temperature and humidity fluctuations are present.

However, there may be potential disadvantages to the use of the nickel layer 302. Nickel tends to have higher electrical resistivity compared to copper, which may introduce additional resistance in the interconnect path. While the configuration of the nickel layer 302 may minimize the increased resistivity effect, it may still be a consideration in applications where maximizing conductivity is useful. For example, by configuring the nickel layer 302 of sufficient thinness, the increased resistivity may be minimized. Additionally, in embodiments that utilize the additional nickel layer 302, the processing and manufacture of such embodiments may implement an additional processing step during manufacturing. This additional processing step may increase production complexity and cost.

Alternatives to the nickel layer 302 include using a palladium-gold (Pd—Au) layer, which may offer better resistance to oxidation and further reduce the risk of IMC formation. Another alternative is the use of cobalt (Co) barriers, which also prevent copper diffusion.

The nickel layer 302 may have any appropriate thickness (i.e., height in the vertical direction). For example, the nickel layer 302 may have a thickness between 0.5 μm and 5 μm, inclusive. The thickness chosen for a particular application may be based on the function of the nickel layer 302 as a diffusion barrier and bonding surface. A thinner nickel layer 302, around 0.5 μm to 1 μm, may be sufficient to prevent copper diffusion while minimizing any increase in electrical resistance or mechanical rigidity. This may be suitable, for example, in fine-pitch applications to meet space and conductivity design targets. The ratio of the thickness of the nickel layer 302 to the thickness of the copper bump 106 may be, for example, in the range of 0.02 to 0.23, inclusive. The ratio of the thickness of the nickel layer 302 to the thickness of the copper pad 104 may be, for example, in the range of 0.05 to 2.5, inclusive.

For applications that require stronger mechanical protection or environments with more aggressive thermal cycling, a thicker nickel layer 302, up to 5 μm, may be used. This added thickness may provide enhanced protection against oxidation and thermal stresses, though it may result in slightly higher resistance and possibly more difficulty in controlling layer uniformity during deposition.

In the example shown in FIG. 6, the width W1 of the opening 112 in the second passivation layer 110 is greater than the width W of the copper bump 106. FIG. 7 is a cross-sectional vertical view of an embodiment configuration with the nickel layer 302 in which the width W1 of the opening 112 in the second passivation layer 110 is less than the width W of the copper bump 106.

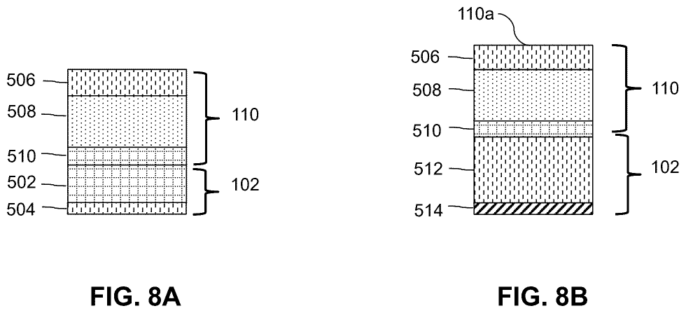

FIG. 8A and FIG. 8B are cross-sectional vertical views illustrating example layer structures of the first passivation layer 102 and the second passivation layer 110. FIG. 8A and FIG. 8B illustrate two distinct configurations of the first passivation layer 102 and the second passivation layer 110 in the interconnect bump structure 100, showcasing different material compositions and stacking sequences that may enhance device performance and reliability and aid in reducing device resistance.

In the configuration shown in FIG. 8A, the first passivation layer 102 may be a bilayer structure. The top layer 502 may be composed of silicon oxynitride (SiO), which provides strong dielectric properties and a moderate level of mechanical protection. SiO may be chosen for its ability to passivate underlying metal layers while still allowing for some flexibility in the device. Beneath this, layer 504 may be formed of silicon nitride (SiN), a dense and durable material known for its excellent barrier properties against moisture and contaminants. SiN also offers mechanical strength and electrical insulation; this may be suitable for protecting sensitive circuitry in harsh environments. The combination of SiO and SiN in the first passivation layer 102 may provide a balanced trade-off between mechanical protection and electrical isolation.

The second passivation layer 110 in FIG. 8A may be a multi-layer structure, composed of three distinct materials. The top layer 506 may be SiN, offering the same advantages as in the first passivation layer 102—high resistance to moisture and superior mechanical strength. The middle layer 508 may be silicon dioxide (SiO₂), a dielectric material that provides excellent electrical insulation and chemical stability. SiO2 is particularly effective in preventing charge leakage and offering strong dielectric properties. The bottom layer 510 may be formed of SiO, similar to the top layer 502 of the first passivation layer 102; the bottom layer 510 may provide additional insulation and protection for the copper pad 104. This layered configuration in the second passivation layer 110 may be useful to provide protection against environmental factors while maintaining electrical performance.

In the alternative structure shown in FIG. 8B, the first passivation layer 102 incorporates a different combination of materials. The top layer 512 may be formed of silicon nitride (SiN), which may be useful for providing robust environmental and mechanical protection. The underlying layer 514 may be formed of silicon carbon nitride (SiCN), which offers enhanced mechanical properties and improved thermal stability compared to SiO. SiCN may be particularly useful, for example, in applications requiring higher resistance to cracking or deformation under thermal cycling conditions. The carbon content of SiCN may improve hardness and resistance to wear, which may make it useful for applications where thermal and mechanical stresses are more prominent.

The second passivation layer 110 in FIG. 8B is identical to that of FIG. 8A, with layers of SiN 506, SiO₂ 508, and SiO 510. This structure may provide strong moisture resistance, electrical insulation, and mechanical integrity. By utilizing different materials in the first passivation layer 102, FIG. 8B offers a higher level of mechanical protection and thermal resistance compared to FIG. 8A, making it suitable for more demanding environments or applications requiring robust durability.

In FIG. 8B, the second passivation layer 110 is depicted with a substantially flat top surface 110a. This flat topography plays enhances the overall performance and reliability of the semiconductor device. A flat top surface 110a of the second passivation layer 110 provides a consistent and uniform interface for subsequent layers, such as metal interconnects or solder bumps; the flat top surface 110a may also improve the bonding quality and reduce the likelihood of defects during assembly.

From a manufacturing perspective, achieving a flat top surface 110a on the second passivation layer 110 may aid in providing uniform deposition of materials in subsequent processing steps, such as the application of redistribution layers (RDLs), solder bumps, or copper bumps. Variations in surface topography, such as irregularities or uneven surfaces, may lead to challenges in lithography, where inconsistent patterning may result in alignment errors or incomplete coverage. By providing a flat top surface 110a, the second passivation layer 110 may provide a more controlled and reliable process. The flat top surface 110a may allow for better alignment of interconnects and higher yields during production.

A flat top surface 110a may contribute to improved mechanical stability of the interconnect bump structure 100. During thermal cycling or mechanical stress, the second passivation layer 110 with a flat top surface 110a may distribute stress more evenly across the surface, reducing the likelihood of crack formation or delamination, which can occur when stress is concentrated at uneven points. This may be useful, for example, in applications in which the interconnect bump structure 100 is exposed to varying thermal conditions, such as in automotive or high-power electronics. Furthermore, the flat top surface 110a facilitates the bonding of components, such as flip-chip packages, in which uniform contact may be useful in ensuring electrical and thermal performance.

In some embodiments, the flat top surface 110a may also enhance the electrical performance of the interconnect bump structure 100. The flat top surface 110a may reduce the risk of parasitic capacitance, which may occur in instances in which uneven surfaces may lead to variations in dielectric thickness between metal layers. Such uneven surfaces may degrade signal integrity, for example, in high-speed or high-frequency applications. By maintaining a uniform passivation surface, the interconnect bump structure 100 shown in FIG. 8B may provide consistent dielectric properties for maintaining signal performance across a resulting semiconductor device.

The flat top surface 110a may be achieved, for example, through various planarization techniques, such as chemical mechanical planarization (CMP), which smooths the surface by removing excess material. CMP and similar techniques allow manufacturers to achieve the necessary precision in surface flatness. The dummy structures 104a, 104b may be useful in achieving the flat top surface 110a.

In some embodiments, there is a ratio Rₚ₁ between the thickness of the SiCN layer 514 and the thickness of the SiN layer 512 of the first passivation layer 102, where 0.05≤Rₚ₁≤0.1. In some embodiments, there is a ratio Rₚ₂ between the thickness of the SiO layer 510 and the thickness of the SiO₂ layer 508 of the second passivation layer 110, where 0.01≤Rₚ₂≤0.1. In some embodiments, there is a ratio Rₚ₃ between the thickness of the SiO₂ layer 508 and the thickness of the SiN layer 510 of the second passivation layer 110, where 1≤Rₚ₃≤10. These ratios may be useful, for example, to ensure sufficient structural integrity and electrical isolation of the first passivation layer 102 and the second passivation layer 110.

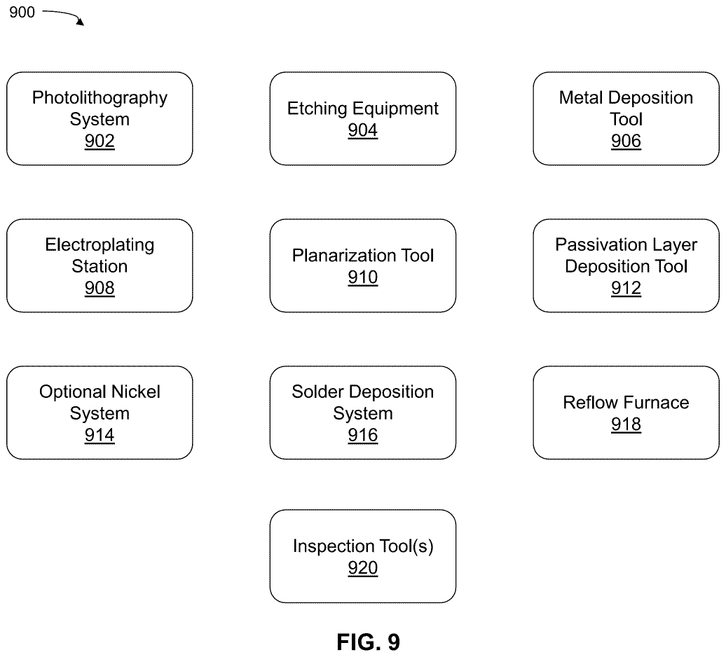

FIG. 9 is a block diagram of an example system 900 for fabricating the interconnect bump structure 100. While a semiconductor device may be serially processed through the various subsystems 902-920 of the system 900, the semiconductor device may be processed through various subsystems in a variety of orders and may be processed by some subsystems multiple times.

The system 900 includes a photolithography system 902. The photolithography system 902 may be used for patterning the first passivation layer 102 and the second passivation layer 110. Photolithography defines where the copper pad 104, copper bump 106, and first passivation layer 102 and second passivation layer 110 may be formed. The photolithography system 902 may include an exposure tool (like a stepper or scanner) that projects a mask image onto a photoresist-coated wafer.

The system 900 includes etching equipment 904. After patterning, etching removes material where the photoresist has been developed. Dry etching (plasma etching) or wet etching tools may be used to etch openings in the first passivation layer 102 and second passivation layer 110 or to define the copper pad area.

The system 900 includes a metal deposition tool 906. The metal deposition tool 906 may be, for example, a sputtering or chemical vapor deposition (CVD) tool. The metal deposition tool 906 may be used to deposit the first metal seed layer, which may be performed before electroplating. Copper, nickel, or barrier layers may be deposited using this equipment.

The system 900 includes an electroplating station 908. The electroplating station 908 may be used for creating the copper pad 104 and copper bump 106. The electroplating station 908 may apply electrical current to deposit thick layers of copper onto the patterned areas of a wafer.

In some embodiments, the electroplating station 908 may be used to create the copper pad 104 as part of a redistribution layer (RDL). Electroplating may be used to deposit copper onto predefined areas of a wafer, forming conductive paths that connect different circuit elements or provide bonding surfaces for further assembly. The process may include deposition of a seed layer, typically a thin copper film, on the wafer's surface. This seed layer provides the necessary electrical conductivity for electroplating, ensuring uniform copper deposition in the subsequent steps.

In the electroplating station 908, the wafer is submerged in a copper sulfate electrolyte solution and connected to the cathode of an external power supply, while an anode, usually made of copper, is also submerged in the solution. When a current is applied, copper ions from the electrolyte solution are reduced and deposited onto the exposed areas of the seed layer, forming the copper pad 104. The patterned photoresist defines the areas where copper should be plated, while unexposed regions remain protected from deposition. The thickness of the copper pad 104 is controlled by the duration of the electroplating process, with typical thicknesses ranging from 1 μm to 10 μm, depending on the application. The electroplating station 908 allows for precise control of the deposition rate and uniformity, which may be useful for creating reliable, low-resistance conductive paths.

One of the advantages of electroplating is its ability to form high-purity, low-resistance copper layers, which may be useful for the electrical performance of the RDL. Electroplating also enables the formation of thick copper pads, which may be useful for handling high current densities or providing robust bonding surfaces for bumps and interconnects. Additionally, electroplating is highly scalable and cost-effective for large-scale production, making it a preferred method in advanced semiconductor packaging.

However, electroplating may have some limitations. One potential disadvantage is the reliance on the seed layer, which in some embodiments must be uniformly deposited before the electroplating step. Any non-uniformities in the seed layer may lead to defects or variations in copper pad thickness. After electroplating, the seed layer must also be etched away from areas where copper is not desired, which may introduce additional processing steps and may potentially damage the underlying structures if not carefully controlled. Furthermore, electroplating may require tight control of solution chemistry and process parameters, such as temperature and current density, to prevent issues like voids, over-plating, or uneven deposition.

Alternatives to electroplating include electroless plating and physical deposition methods. In electroless plating, copper is deposited chemically without the need for an external current. This method may plate copper on non-conductive surfaces and is useful for applications requiring uniform deposition across complex geometries, but it may produce thinner films with lower conductivity compared to electroplating. Sputtering or evaporation are physical deposition methods that can also be used to form copper pads; however, these techniques may be more expensive and less efficient for building up thick layers of copper, making them less suitable for applications requiring robust interconnects.

The system 900 includes a planarization tool 910. The planarization tool 910 may be, for example, a chemical mechanical planarization tool (CMP). The planarization tool 910 may be used to flatten one or more of the surfaces. Flattening surfaces may be useful, for example, to ensure uniformity, especially if there are bumps and uneven layers.

The system 900 includes a passivation layer deposition tool 912. The passivation layer deposition tool 912 may deposit the first passivation layer 102 and the second passivation layer 110 (SiO₂, SiN, or other materials). The passivation layer deposition tool 912 may be, for example, a Plasma-Enhanced Chemical Vapor Deposition (PECVD) system or Low-Pressure CVD (LPCVD) for the deposition of insulating materials.

The system 900 may include a nickel deposition system 914 for configurations where a nickel layer 302 is deposited on the copper bump 106. In embodiments including the nickel layer 302, the nickel deposition system 914 may include a Physical Vapor Deposition (PVD) tool or electroplating tool for depositing the nickel layer 302 on top of the copper bump 106.

The system 900 includes a solder deposition system 916. For the deposition of the tin-silver bump 108, any of several appropriate methods may be used. A solder ball placement tool may place pre-formed solder balls on the copper or nickel bumps. Alternatively, a screen-printing system may deposit solder paste.

The system 900 includes a reflow furnace 918. After the tin-silver bump 108 is deposited, the reflow furnace 918 may be used to heat the solder, allowing it to melt and form a solid connection to the copper bump 106.

The system 900 includes one or more inspection tools 920. For example, the inspection tools 920 may be configured to monitor the thickness, quality, and alignment of each layer, including Optical Inspection tools, Scanning Electron Microscopes (SEM), and profilometers.

The system 900 includes a bonding station 922. The bonding station 922 may perform, for example, thermocompression bonding or reflow soldering. The bonding station 922 bonds a component to the copper bump 106 and copper pad 104 and creates an electrical and mechanical connection.

In thermocompression bonding, the bonding station 922 may use controlled pressure and heat to bond the copper bump 106 to a corresponding metal pad on the other component, while the tin-silver bump 108 forms the final connection. The bonding station 922 may be equipped with a precision heating mechanism that applies heat to the copper bump 106 and tin-silver bump 108, causing the tin-silver alloy to reflow and form a robust, low-resistance connection. The copper bump 106 may serve as a rigid structural support during this process. The bonding station 922 may also precisely align the other component with the substrate, for example, by utilizing optical systems to ensure sub-micron alignment accuracy. A combination of mechanical force and thermal energy may be used to create proper metallurgical bonding without damaging potentially fragile semiconductor layers.

Alternatively, in reflow soldering-based bonding, the bonding station 922 may include a chamber where the entire assembly (copper bump 106 and the other component) is heated to the melting point of the tin-silver solder. As the solder melts, it forms strong mechanical and electrical joints between the copper bump 106 and a corresponding bump on the other component. Once the solder cools, the solder solidifies, creating a reliable electrical path and mechanical support between the die and substrate.

FIGS. 10A-10C illustrate an example bonding process using the copper bump 106 on the copper pad 104. The copper bump 106 is bonded to a component 702 having an interconnect pad 704 (also referred to as a top bonding pad or top bonding bump). The component 702 may be, for example, a semiconductor die or chip or any other appropriate type of component in semiconductor manufacturing. The interconnect pad 704 may be another copper bump having a tin-silver bump or any other appropriate type of structure for bonding to the copper bump 106 on the copper pad 104.

FIG. 10A illustrates the component 702 being moved into position to align the interconnect pad 704 with the copper bump 106 on the copper pad 104. FIG. 10B illustrates the interconnect bump structure 100 after the bonding process creates a solder joint 706. While the solder bump 108 may have a width of W which may be substantially equal to the width of the copper bump 106 before the bonding process, after the bonding process, the solder bump 108 may have a width W2 in the horizontal direction, where 21 μm≤W2≤45 μm. This transformation of solder bump 108 width from a width W to a solder joint 706 width W2 may be due to the compression of the solder bump 108 and the reflow process to reshape the solder bump 108. The interconnect pad 704 may be compressed into the solder joint 706 to displace some of the solder bump 108 material. After the bonding process the solder bump 108 may become the solder joint 108. The solder joint 108 may have a height H2 in the vertical direction, where 4 μm≤H2≤10 μm.

A solder mask 710 may be used in the process. The solder mask 710 is a protective layer applied, for example, to prevent solder bridges between closely spaced connections during the soldering process. The solder mask 710 may be a liquid polymer that solidifies upon curing. The solder mask 710 may have a height H3 in the vertical direction, where 0 μm≤H2≤20 μm. These dimensions may be selected for the solder joint 108 to provide sufficient mechanical strength and electrical conductivity while meeting size, weight, and cost design targets.

In some embodiments, a ratio R_{W2} between the width W of the copper bump 106 and the width W2 of the solder joint 706 is between 1 and 2, inclusive. Adjusting the dimensions of the copper bump 106 and the solder joint 706 in this manner, i.e., such that the solder joint 706 is somewhat wider than the copper bump 106, may be useful to ensure that the mechanical strength and electrical connectivity of the solder joint 706 meet design targets.

FIG. 10C shows the interconnect bump structure 100 after application of underfill material 708. The underfill material 708 may be applied in liquid form. The underfill material 708 may be an epoxy resin with fine filler particles that flow into gaps, surrounding the solder joint 706 and copper bump 106. The underfill material 708 may be dispensed such that capillary action allows the underfill material 708 to flow and fill the available space. Then, the underfill material 708 may be cured, for example, through heating, to harden the underfill material 708. The cured underfill material 708 may protect the solder joint 706 from mechanical stresses such as thermal expansion and contraction during operation.

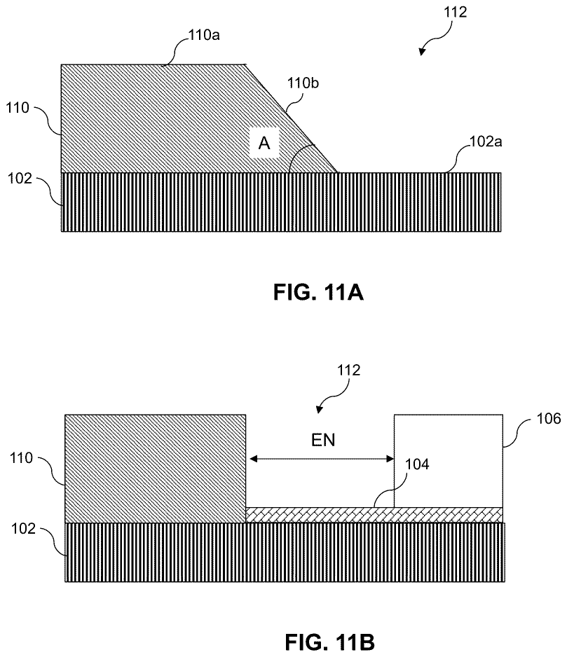

FIG. 11A is a cross-sectional vertical view of the interconnect bump structure 100 showing a portion of the second passivation layer 110 at an intersection with the opening 112 in the second passivation layer 110 such as in FIGS. 1, 2-4, and 6. In some embodiments, the second passivation layer 110 has a sloped sidewall 110b that slopes from the flat top surface 110a of the second passivation layer 110 to a top surface 102a of the first passivation layer 102.

The sloping of the sloped sidewall 110b creates an angle A between the sloped sidewall 110b and the top surface 102a of the first passivation layer 102. The angle A may be, for example, between 60° and 90°, inclusive. The particular angle A selected for a given application may be selected to provide sufficient height for the second passivation layer 110 to protect the interconnect bump structure 100 while also providing sufficient width for the opening 112 in the second passivation layer 110 to allow room for the formation of the copper bump 106.

FIG. 11B is a cross-sectional vertical view of the interconnect bump structure 100 showing a portion of the second passivation layer 110 at an intersection with the opening 112 in the second passivation layer 110. In some embodiments, a distance EN between the second passivation layer 110 and the copper bump 106 is less than or equal to 12 μm. Keeping this distance EN sufficiently low may be useful, for example, to protect underlying circuitry and meet electrical isolation design targets. By minimizing the distance EN, the coverage of the second passivation layer 110 may be increased to enhance the protection to the copper pad 104, but continue to provide space to form the copper bump 106.

The following discussion now refers to a number of methods and method steps. Although the method steps are discussed in specific orders or are illustrated in a flow chart as being performed in a particular order, no order is required unless expressly stated or required because a step is dependent on another step being completed prior to the step being performed.

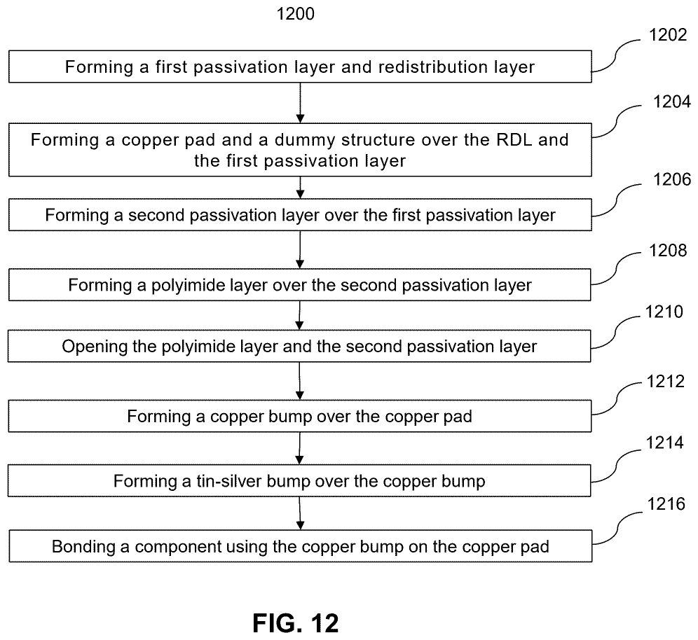

Embodiments are now described in connection with FIG. 12, which illustrates a flow diagram of an example method 1200 for fabricating an interconnect bump structure 100 according to some embodiments of the present disclosure.

In an embodiment method 1200, step 1202 comprises forming a first passivation layer 102 and a RDL 116. In an embodiment method 1220, step 1204 comprises forming a copper pad 104 and a dummy structure 104a, 104b over the landing pad 116 and the first passivation layer 102.

In an embodiment method 1200, step 1206 comprises forming a second passivation layer 110 over the first passivation layer 102. Forming the second passivation layer 110 may include, for example, depositing the second passivation layer 110 to form a substantially flat top surface 110a and patterning and etching the second passivation layer 110 such that the opening 112 in the second passivation layer 110 has a width between 32 μm and 43 μm, inclusive.

In an embodiment method 1200, step 1208 comprises forming a polyimide layer 118 over the second passivation layer 110. The polyimide layer 118 may be cut flush with the second passivation layer 110 or have a wider opening than the second passivation layer 110.

In an embodiment method 1200, step 1210 comprises opening the polyimide layer 118 and the second passivation layer 110 to expose the copper pad 104. In an embodiment method 1200, step 1212 comprises forming a copper bump 106 on the copper pad 104. In an embodiment method 1200, step 1214 comprises forming a tin-silver bump 108 over the copper bump 106. Forming the tin-silver bump 108 may include forming a nickel layer 302 on the copper bump 106 and then forming the tin-silver bump 108 over the nickel layer 302.

In an embodiment method 1200, step 1216 comprises bonding a component 702 using the copper bump 106 on the copper pad 104. For example, bonding the component 702 may include performing thermocompression bonding or reflow soldering bonding. The component 702 may be a semiconductor die or chip or other appropriate type of component.

In some embodiments, the interconnect bump structure 100 undergoes an inspection to ensure that the copper bump 106 and the tin-silver bump 108 meet the required dimensional and quality standards. Automated optical inspection (AOI) and scanning electron microscopy (SEM) may be used for this purpose. The copper bump 106 and the tin-silver bump 108 may be electrically tested to verify that the Rc values are within specified ranges.

The various embodiments disclosed herein may provide various advantages and improvements. The low electrical resistance of the copper pad 104 may contribute to a lower device resistance, for example, compared to devices that use aluminum pads. The lower resistance may alleviate signal delays and signal distortion. The lower resistance may increase the maximum frequency at which a circuit can operate. The lower resistance may increase the overall performance and reliability of the interconnect bump structure 100. Moreover, good adhesion between the first passivation layer 102 and/or the second passivation layer 110 and the copper pad 104 may improve reliability and extend the operational life of the interconnect bump structure 100.

Referring to all drawings and according to various embodiments of the present disclosure, an interconnect bump structure 100 may be provided. The interconnect bump structure 100 may include a first passivation layer 102; a copper pad formed over the first passivation layer 102; a copper bump 106 formed over the copper pad 104; solder material 108 over the copper bump 106; and a second passivation layer 110 formed over the first passivation layer 102, wherein the copper bump 106 is formed through an opening 112 in the second passivation layer 110.

In one embodiment a ratio R_{W} between a width of the copper bump 106 and a width of the opening 112 in the second passivation layer 110 is between 0.4 and 2, inclusive. In one embodiment the second passivation layer 110 comprises a substantially flat top surface 110a. In one embodiment the first passivation layer 102 comprises a layer of SiN formed over a layer of SiCN. In one embodiment the second passivation layer 110 comprises layer of SiN formed over a layer of SiO₂ which is formed over a layer of SiO. In one embodiment the interconnect bump structure comprises an auxiliary layer 302 on the copper bump 106 and the tin-silver bump 108 is on the auxiliary layer 302 and the auxiliary layer 302 comprises at least one of nickel, palladium-gold, or cobalt. In one embodiment the second passivation layer 110 comprises a sloped sidewall 110b that slopes from a flat top surface 110a of the second passivation layer 110 to a top surface 102a of the first passivation layer 102. In one embodiment the sloped sidewall 110b creates an angle A between the sloped sidewall 110b and the top surface 102a of the first passivation layer 102 and the angle A is between 60° and 90°, inclusive. In one embodiment, the copper bump 106 and the solder material 108 form a conductive terminal providing an electrical connection for a ground or power supply voltage between the interconnect bump structure and an external component 702. In one embodiment the interconnect bump structure comprises a polyimide layer 118 over the second passivation layer 110.

An additional embodiment is drawn to an interconnect bump structure comprising a copper pad 104, a dummy structure 104a, 104b adjacent to the copper pad 104, a copper bump 106 on the copper pad 104, and a tin-silver bump 108 over the copper bump 106. The interconnect bump structure comprises a passivation layer 110 supported by the dummy structure 104a, 104b such that the second passivation layer 110 comprises a substantially flat top surface 110a. The copper bump 106 passes through an opening 112 in the passivation layer 110. A top surface of the dummy structure 104a, 104b is covered by the passivation layer 110.

In an embodiment, the copper pad 104 has a circular shape. In an embodiment, the copper dummy structure 104a, 104b comprises copper dummy pads 104a, 104b on opposite sides of the copper pad 104. In an embodiment, the copper bump 106 has a width between 21 μm and 35 μm, inclusive, and wherein the opening 112 in the passivation layer 110 has a width between 32 μm and 43 μm, inclusive. In an embodiment, a ratio R_{W} between a width of the copper bump 106 and a width of the opening 112 in the passivation layer 110 is between 0.4 and 2, inclusive.

An additional embodiment is drawn to a method of forming an interconnect bump structure. The method comprises forming a first passivation layer 102, forming a copper pad 104 over the first passivation layer 102, forming a second passivation layer 110 over the first passivation layer 102, forming a copper bump 106 on the copper pad 104 such that the copper bump 106 passes through an opening 112 in the second passivation layer 110, and forming a tin-silver bump 108 over the copper bump 106.

In an embodiment, the method comprises forming a polyimide layer 118 over the second passivation layer 110. In an embodiment, forming the copper pad 104 further comprises forming a copper dummy structure 104a, 104b adjacent to the copper pad 104. In an embodiment, forming the copper pad 104 comprises forming the copper pad 104 in a circular shape, and forming the copper dummy structure 104a, 104b comprises forming the copper dummy structure 104a, 104b as copper dummy pads 104a, 104b on opposite sides of the copper pad 104. In an embodiment, forming the second passivation layer 110 comprises depositing the second passivation layer 110 to form a substantially flat top surface 110a and patterning and etching the second passivation layer 110 such that the opening 112 in the second passivation layer 110 has a width between 32 μm and 43 μm, inclusive. In an embodiment, the method comprises forming a nickel layer 302 on the copper bump 106, wherein depositing the tin-silver bump 108 comprises depositing the tin-silver bump 108 on the nickel layer 302.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An interconnect bump structure comprising:
a first passivation layer;
a copper pad formed over the first passivation layer;
a copper bump formed over the copper pad;
solder material formed over the copper bump; and
a second passivation layer formed over the first passivation layer, wherein the copper bump is formed through an opening in the second passivation layer.

2. The interconnect bump structure of claim 1, wherein a ratio R_{W} between a width of the copper bump and a width of the opening in the second passivation layer is between 0.4 and 2, inclusive.

3. The interconnect bump structure of claim 1, wherein the second passivation layer comprises a substantially flat top surface.

4. The interconnect bump structure of claim 1, wherein the first passivation layer comprises a layer of SiN formed over a layer of SiCN.

5. The interconnect bump structure of claim 1, wherein the second passivation layer comprises layer of SiN formed over a layer of SiO₂ which is formed over a layer of SiO.

6. The interconnect bump structure of claim 1, comprising an auxiliary layer on the copper bump, wherein the solder material is on the auxiliary layer, and wherein the auxiliary layer comprises at least one of nickel, palladium-gold, or cobalt.

7. The interconnect bump structure of claim 1, wherein the second passivation layer comprises a sloped sidewall that slopes from a top surface of the second passivation layer to a top surface of the first passivation layer, and wherein the sloped sidewall creates an angle A between the sidewall and the top surface of the first passivation layer, and wherein the angle A is between 60° and 90°, inclusive.

8. The interconnect bump structure of claim 1, wherein the copper bump and the solder material form a conductive terminal providing an electrical connection for a ground or power supply voltage between the interconnect bump structure and an external component, the conductive terminal including a solder region and an intermetallic compound (IMC) region.

9. The interconnect bump structure of claim 1, comprising a polyimide layer over the second passivation layer.

10. An interconnect bump structure comprising:
a copper pad;
a dummy structure adjacent to the copper pad;
a copper bump formed over the copper pad;
a tin-silver bump formed over the copper bump; and
a passivation layer supported by the dummy structure such that the passivation layer comprises a substantially flat top surface,
wherein the copper bump passes through an opening in the passivation layer, and
wherein a top surface of the dummy structure is covered by the passivation layer.

11. The interconnect bump structure of claim 10, wherein the copper pad has a circular shape.

12. The interconnect bump structure of claim 11, wherein the dummy structure comprises copper dummy pads on opposite sides of the copper pad.

13. The interconnect bump structure of claim 10, wherein the copper bump has a width between 21 μm and 35 μm, inclusive, and wherein the opening in the passivation layer has a width between 32 μm and 43 μm, inclusive.

14. The interconnect bump structure of claim 11, wherein a ratio R_{W} between a width of the copper bump and a width of the opening in the passivation layer is between 0.4 and 2, inclusive.

15. A method of forming an interconnect bump structure, the method comprising:
depositing a first passivation layer;
forming a copper pad over the first passivation layer;
depositing a second passivation layer over the first passivation layer;
forming a copper bump on the copper pad such that the copper bump passes through an opening in the second passivation layer; and
forming a tin-silver bump over the copper bump.

16. The method of claim 15, comprising depositing a polyimide layer over the second passivation layer.

17. The method of claim 15, wherein forming the copper pad further comprises forming a copper dummy structure adjacent to the copper pad.

18. The method of claim 15, wherein forming the copper pad comprises forming the copper pad in a circular shape, and wherein forming the copper dummy structure comprises forming copper dummy pads on opposite sides of the copper pad.

19. The method of claim 15, wherein depositing the second passivation layer comprises depositing the second passivation layer to form a substantially flat top surface and patterning and etching the second passivation layer such that the opening in the second passivation layer has a width between 32 μm and 43 μm, inclusive.

20. The method of claim 15, comprising forming a nickel layer on the copper bump, wherein depositing the tin-silver bump comprises depositing the tin-silver bump on the nickel layer.
